(19) United States
(12) Patent Application Publication
(10) Pub. No.: US 2024/0234499 A1
(43) Pub. Date: Jul. 11, 2024

(54) SEMICONDUCTOR DEVICE AND METHOD OF MANUFACTURING THE SAME

(71) Applicant: DB HITEK CO., LTD., Seoul (KR)

(72) Inventor: Kyu Ok LEE, Eumseong-gun (KR)

(21) Appl. No.: 18/137,331

(22) Filed: Apr. 20, 2023

(30) Foreign Application Priority Data
Jan. 5, 2023 (KR) 10-2023-0001936

(51) Int. Cl. H01L 29/06; H01L 21/02; H01L 29/66; H01L 29/78

(52) U.S. Cl. CPC H01L 29/0653; H01L 21/02238; H01L 21/02255; H01L 29/66681; H01L 29/7816

(57) ABSTRACT

A semiconductor device includes a field oxide layer formed on a substrate, a gate insulating layer formed on a surface portion of the substrate adjacent to one side of the field oxide layer, a gate electrode formed on the gate insulating layer and a portion of the field oxide layer, a source region formed in a surface portion of the substrate adjacent to one side of the gate electrode, and a drain region formed in a surface portion of the substrate adjacent to another side of the field oxide layer. A surface portion of the substrate on which the field oxide layer is formed is convex upward.

### CROSS-REFERENCE TO RELATED APPLICATION

This application claims the priority benefit of Korean Patent Application No. 10-2023-0001936, filed on Jan. 5, 2023, and all the benefits accruing therefrom under 35 U.S.C. § 119, the contents of which are incorporated by reference in their entirety.

### TECHNICAL FIELD

The present disclosure relates to a semiconductor device and a method of manufacturing the same. More specifically, the present disclosure relates to a high voltage semiconductor device such as a Lateral Double Diffused Metal Oxide Semiconductor (LDMOS) device and a method of manufacturing the same.

### BACKGROUND

Semiconductor devices such as LDMOS devices may be used in application circuits such as power switching circuits. The LDMOS device may include a gate electrode formed on a substrate, a source region and a drain region formed in surface portions of the substrate adjacent to the gate electrode, and a field oxide layer formed on a surface portion of the substrate between the gate electrode and the drain region. The field oxide layer may be used to increase the breakdown voltage of the LDMOS device.

In addition, the LDMOS device may include a drift region formed in the substrate, and the field oxide layer and the drain region may be formed on the drift region. For example, the field oxide layer may be formed through a Local Oxidation of Silicon (LOCOS) process. In such case, because the moving distance of electrons through the drift region under the field oxide layer may be increased, and thus, the on-resistance of the LDMOS device may be increased.

As another example, a field oxide pattern may be formed by forming a silicon oxide layer on the substrate through a chemical vapor deposition process and patterning the silicon oxide layer through an etching process. In the case of using the field oxide pattern, the moving distance of electrons may be reduced. However, the threshold voltage of the LDMOS device may increase and the current may decrease due to defects generated during the chemical vapor deposition process and the etching process.

### SUMMARY

The present disclosure is to solve the above problems and provides a semiconductor device having improved electrical characteristics compared to the prior art and a method of manufacturing the same.

In accordance with an aspect of the present disclosure, a semiconductor device may include a field oxide layer formed on a substrate, a gate insulating layer formed on a surface portion of the substrate adjacent to one side of the field oxide layer, a gate electrode formed on the gate insulating layer and a portion of the field oxide layer, a source region formed in a surface portion of the substrate adjacent to one side of the gate electrode, and a drain region formed in a surface portion of the substrate adjacent to another side of the field oxide layer. Particularly, a surface portion of the substrate on which the field oxide layer is formed may be convex upward.

In accordance with some embodiments of the present disclosure, the field oxide layer may have a width that gradually increases downward.

In accordance with some embodiments of the present disclosure, the semiconductor device may further include a drift region formed in the substrate and a body region formed in the substrate. In such case, the source region may be formed in a surface portion of the body region, and the drain region may be formed in a surface portion of the drift region.

In accordance with some embodiments of the present disclosure, the semiconductor device may further include a body contact region formed in a surface portion of the body region adjacent to one side of the source region.

In accordance with another aspect of the present disclosure, a method of manufacturing a semiconductor device may include forming a field oxide layer on a substrate, forming a gate insulating layer on a surface portion of the substrate adjacent to one side of the field oxide layer, forming a gate electrode on the gate insulating layer and a portion of the field oxide layer, forming a source region in a surface portion of the substrate adjacent to one side of the gate electrode, and forming a drain region in a surface portion of the substrate adjacent to another side of the field oxide layer. Particularly, a surface portion of the substrate on which the field oxide layer is formed may be convex upward while the field oxide layer is formed.

In accordance with some embodiments of the present disclosure, forming the field oxide layer may include forming a silicon layer on the substrate, forming a hard mask pattern on the silicon layer to expose a portion of the silicon layer, performing a first thermal oxidation process to oxidize the exposed portion of the silicon layer so that a preliminary field oxide layer having a bird's beak-shaped side portion is formed, removing the hard mask pattern, etching the silicon layer so that a ring-shaped silicon pattern remains under the side portion of the preliminary field oxide layer, and performing a second thermal oxidation process to oxidize the ring-shaped silicon pattern so that the field oxide layer is formed.

In accordance with some embodiments of the present disclosure, forming the field oxide layer may further include forming a pad oxide layer on the substrate. In such case, the silicon layer may be formed on the pad oxide layer.

In accordance with some embodiments of the present disclosure, forming the field oxide layer may further include removing the pad oxide layer after performing the second thermal oxidation process.

In accordance with some embodiments of the present disclosure, the first thermal oxidation process may be performed until the preliminary field oxide layer is reached on the pad oxide layer.

In accordance with some embodiments of the present disclosure, the method may further include forming a body region and a drift region in the substrate before forming the field oxide layer. In such case, the source region may be formed in a surface portion of the body region, and the drain region may be formed in a surface portion of the drift region.

In accordance with some embodiments of the present disclosure, the method may further include forming a body contact region in a surface portion of the body region adjacent to one side of the source region.

In accordance with still another aspect of the present disclosure, a method of manufacturing a semiconductor device may include forming a silicon layer on a substrate, forming a hard mask pattern on the silicon layer to expose a portion of the silicon layer, performing a first thermal oxidation process to oxidize the exposed portion of the silicon layer so that a preliminary field oxide layer having a bird's beak-shaped side portion is formed, removing the hard mask pattern, performing a first etch-back process so that a ring-shaped silicon pattern remains under the side portion of the preliminary field oxide layer, performing a second thermal oxidation process to oxidize the ring-shaped silicon pattern so that a field oxide layer is formed, performing a second etch-back process until the substrate is exposed, forming a gate insulating layer on a surface portion of the substrate adjacent to one side of the field oxide layer, forming a gate electrode on the gate insulating layer and a portion of the field oxide layer, forming a source region in a surface portion of the substrate adjacent to one side of the gate electrode, and forming a drain region in a surface portion of the substrate adjacent to another side of the field oxide layer.

In accordance with some embodiments of the present disclosure, the method may further include forming a pad oxide layer on the substrate. In such case, the silicon layer may be formed on the pad oxide layer.

In accordance with some embodiments of the present disclosure, the pad oxide layer may be removed by the second etch-back process.

In accordance with some embodiments of the present disclosure, the first thermal oxidation process may be performed until the preliminary field oxide layer is reached on the pad oxide layer.

In accordance with some embodiments of the present disclosure, the method may further include forming a body region and a drift region in the substrate before forming the silicon layer. In such case, the source region may be formed in a surface portion of the body region, and the drain region may be formed in a surface portion of the drift region.

In accordance with some embodiments of the present disclosure, the method may further include forming a body contact region in a surface portion of the body region adjacent to one side of the source region.

In accordance with the embodiments of the present disclosure as described above, the surface portion of the substrate on which the field oxide layer is formed may be convex upward, and thus, the moving distance of electrons moving from the source region to the drain region and the on-resistance of the semiconductor device may be reduced. In addition, the interface between the field oxide layer and the substrate may be spaced upward from the movement path of the electrons. Accordingly, the Hot Carrier Injection (HCI) effect may be reduced, and the threshold voltage of the semiconductor device may be stably maintained in comparison with the prior art using the field oxide pattern.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating a semiconductor device in accordance with an embodiment of the present disclosure; and

FIGS. 2 to 8 are schematic cross-sectional views illustrating a method of manufacturing the semiconductor device as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present disclosure are described in more detail with reference to the accompanying drawings. However, the present disclosure is not limited to the embodiments described below and is implemented in various other forms. Embodiments below are not provided to fully complete the present disclosure but rather are provided to fully convey the range of the present disclosure to those skilled in the art. In the specification, when one component is referred to as being on or

connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present disclosure, the regions and the layers are not limited to these terms.

Terminologies used below are used to merely describe specific embodiments, but do not limit the present disclosure. Additionally, unless otherwise defined here, all the terms including technical or scientific terms, may have the same meaning that is generally understood by those skilled in the art.

Embodiments of the present disclosure are described with reference to schematic drawings of ideal embodiments. Accordingly, changes in manufacturing methods and/or allowable errors may be expected from the forms of the drawings. Accordingly, embodiments of the present disclosure are not described being limited to the specific forms or areas in the drawings, and include the deviations of the forms. The areas may be entirely schematic, and their forms may not describe or depict accurate forms or structures in any given area, and are not intended to limit the scope of the present disclosure.

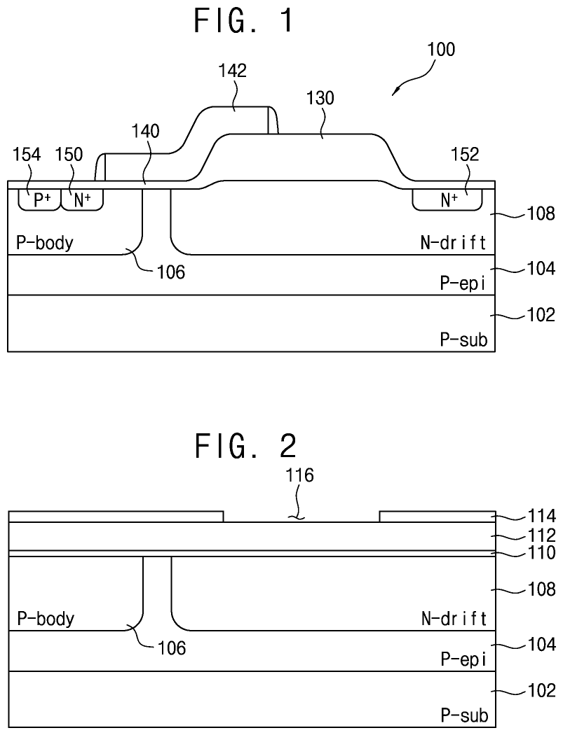

FIG. 1 is a schematic cross-sectional view illustrating a semiconductor device in accordance with an embodiment of the present disclosure.

Referring to FIG. 1, a semiconductor device 100, in accordance with an embodiment of the present disclosure, may be used as an LDMOS device, and may include a field oxide layer 130 formed on a substrate 102, a gate insulating layer 140 formed on a surface portion of the substrate 102 adjacent to one side of the field oxide layer 130, a gate electrode 142 formed on the gate insulating layer 140 and a portion of the field oxide layer 130, a source region 150 formed in a surface portion of the substrate 102 adjacent to one side of the gate electrode 142, and a drain region 152 formed in a surface portion of the substrate 102 adjacent to another side of the field oxide layer 130, for example, to an opposite side of the field oxide layer 130.

A body region 106 and a drift region 108 may be formed in the substrate 102. The substrate 102 may have a first conductivity type, and the drift region 108 may have a second conductivity type. For example, a P-type substrate may be used as the substrate 102, and the drift region 108 may be an N-type impurity diffusion region. The body region 106 may have the first conductivity type. For example, the body region 106 may be a P-type impurity diffusion region.

In addition, as shown in FIG. 1, the substrate 102 may include a P-type epitaxial layer 104. In such case, the body region 106 and the drift region 108 may be formed in the P-type epitaxial layer 104. For example, the source region 106 may be formed by implanting P-type impurities into the P-type epitaxial layer 104, and the drift region 108 may be formed by implanting N-type impurities into the P-type epitaxial layer 104. Further, as shown in FIG. 1, the drift region 108 may be laterally spaced apart from the body region 106 by a predetermined distance.

The source region 150 may be formed in a surface portion of the body region 106 adjacent to one side of the gate electrode 142, and the drain region 152 may be formed in a surface portion of the drift region 108 adjacent to another side of the field oxide layer 130. The source region 150 and the drain region 152 may have the second conductivity type. For example, high-concentration N-type impurity diffusion regions may be used as the source region 150 and the drain region 152.

A body contact region 154 may be formed in a surface portion of the body region 106 adjacent to one side of the source region 150. The body contact region 154 may have the first conductivity type. For example, a high-concentration P-type impurity diffusion region may be used as the body contact region 154.

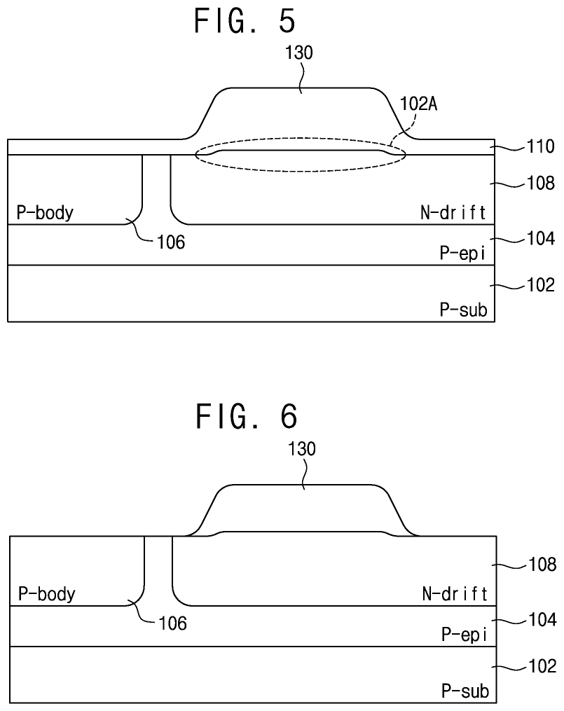

In accordance with an embodiment of the present disclosure, as shown in FIG. 1, a surface portion 102A (refer to FIG. 5) of the substrate 102 on which the field oxide layer 130 is formed may be convex upward. That is, a surface portion of the substrate 102 on which the gate insulating layer 140 is formed may be lower than the surface portion 102A of the substrate 102 on which the field oxide layer 130 is formed. Therefore, in comparison with the prior art using a field oxide layer formed through a LOCOS process, the movement distance of electrons moving from the source region 150 to the drain region 152 may be reduced, and accordingly, the on-resistance of the semiconductor device 100 may be reduced.

Further, the interface between the field oxide layer 130 and the substrate 102 may be spaced upward from the movement path of the electrons. Accordingly, the HCI effect in which the electrons are trapped in the interface portions between the field oxide layer 130 and the substrate 102 may be reduced. As a result, the threshold voltage of the semiconductor device 100 may be stably maintained in comparison with the prior art using the field oxide pattern.

In addition, as shown in FIG. 1, the field oxide layer 130 may have an outwardly inclined side surface. That is, the field oxide layer 130 may have a width that gradually increases downward. Accordingly, the concentration of electric field between the gate insulating layer 140 and the field oxide layer 130 may be reduced.

FIGS. 2 to 8 are schematic cross-sectional views illustrating a method of manufacturing the semiconductor device as shown in FIG. 1.

Referring to FIG. 2, a body region 106 and a drift region 108 may be formed in a substrate 102. The substrate 102 and the body region 106 may have a first conductivity type, and the drift region 108 may have a second conductivity type. For example, a P-type substrate may be used as the substrate 102 and may include a P-type epitaxial layer 104 as shown in FIG. 2. In such case, the body region 106 and the drift region 108 may be formed in the P-type epitaxial layer 104. For example, the body region 106 may be a P-type impurity diffusion region formed by an ion implantation process, and the drift region 108 may be an N-type impurity diffusion region formed by an ion implantation process. Further, the drift region 108 may be laterally spaced apart from the source region 106 by a predetermined distance.

A pad oxide layer 110 may be formed on the substrate 102. For example, the pad oxide layer 110 may be formed through a thermal oxidation process to reduce defects at an interface with the substrate 102. A silicon layer 112 may be formed on the pad oxide layer 110. For example, a polysilicon layer or an amorphous silicon layer may be formed on the pad oxide layer 110 through a chemical vapor deposition process.

A hard mask pattern 114 having an opening 116 exposing a portion of the silicon layer 112 may be formed on the silicon layer 112. The hard mask pattern 114 may be made of silicon nitride, and the opening 116 may be formed above the drift region 108. For example, the hard mask pattern 114 may be formed by forming a silicon nitride layer on the silicon layer 112 and then patterning the silicon nitride layer.

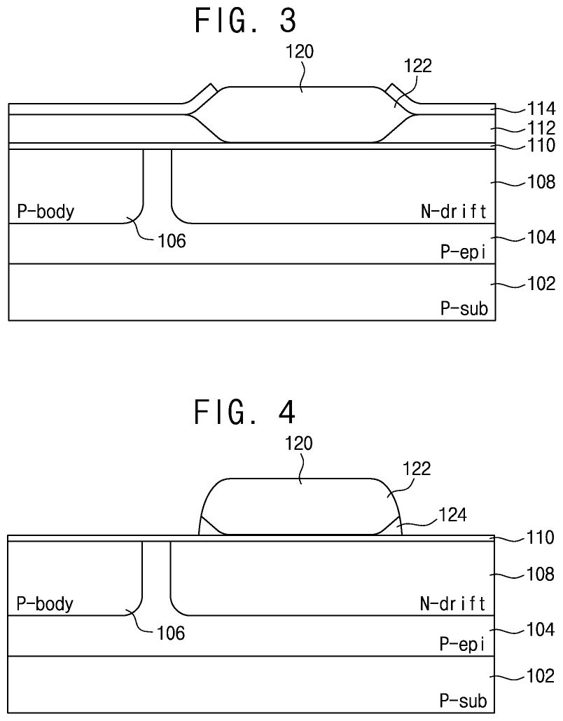

Referring to FIG. 3, a first thermal oxidation process may be performed to oxidize the portion of the silicon layer 112 exposed by the hard mask pattern 114. A preliminary field oxide layer 120 including a side portion 122 having a bird's beak shape may be formed on the pad oxide layer 110 by the first thermal oxidation process. In such case, the first thermal oxidation process may be performed until the preliminary field oxide layer 120 is reached on the pad oxide layer 110.

Referring to FIG. 4, after forming the preliminary field oxide layer 120, the hard mask pattern 114 may be removed. For example, the hard mask pattern 114 may be removed through a wet etching process.

Then, the silicon layer 112 may be etched so that a ring-shaped silicon pattern 124 remains under the side portion 122 of the preliminary field oxide layer 120. For example, a first etch-back process may be performed, whereby the ring-shaped silicon pattern 124 may remain under the side portion 122 of the bird's beak shape.

Referring to FIG. 5, a second thermal oxidation process may be performed to form a field oxide layer 130 on the substrate 102. The ring-shaped silicon pattern 124 may be oxidized by the second thermal oxidation process. In particular, a thickness of the pad oxide layer 110 may be increased, except for a portion on which the preliminary field oxide layer 120 is formed. As a result, a field oxide layer 130 including the preliminary field oxide layer 120, a portion of the pad oxide layer 110 under the preliminary field oxide layer 120, and an oxide portion formed from the ring-shaped silicon pattern 124 may be formed on the substrate 102.

In particular, as shown in FIG. 5, the thickness of the pad oxide layer 110 may be increased by the second thermal oxidation process, and accordingly, a surface portion (a portion indicated by a dotted line) 102A of the substrate 102 on which the field oxide layer 130 is formed may relatively protrude upward. In addition, as the ring-shaped silicon pattern 124 is oxidized, the field oxide layer 130 may have a width gradually increasing downward and a side surface inclined outward.

Referring to FIG. 6, after forming the field oxide layer 130, a second etch-back process may be performed until the substrate 102 is exposed, thereby removing the pad oxide layer 110. At this time, a surface portion of the field oxide layer 130 may be removed by the second etch-back process, and thereby a thickness of the field oxide layer 130 may be reduced by the thickness of the pad oxide layer 110.

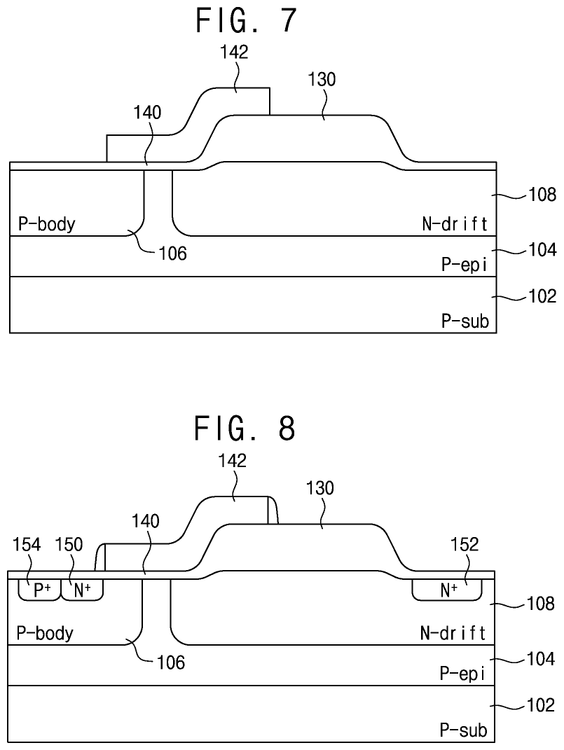

Referring to FIG. 7, a gate insulating layer 140 may be formed on a surface portion of the substrate 102 adjacent to one side of the field oxide layer 130. For example, a thermal oxidation process may be performed after removing the pad oxide layer 110, thereby forming a silicon oxide layer on the substrate 102.

Subsequently, a gate electrode 142 may be formed on the gate insulating layer 140 and a portion of the field oxide layer 130. For example, the gate electrode 142 may be formed above a portion of the body region 106, a portion of the drift region 108, and a portion of the P-type epitaxial layer 104 between the body region 106 and the drift region 108 as shown in FIG. 7. For example, the gate electrode 142 may be formed by forming an impurity-doped polysilicon layer on the field oxide layer 130 and the silicon oxide layer, and then patterning the impurity-doped polysilicon layer. In such case, a portion of the silicon oxide layer formed between the gate electrode 142 and the substrate 102 may function as the gate insulating layer 140.

Referring to FIG. 8, a source region 150 may be formed in a surface portion of the substrate 102 adjacent to one side of the gate electrode 142, and a drain region 152 may be formed in a surface portion of the substrate 102 adjacent to another side of the field oxide layer 130. For example, the source region 150 and the drain region 152 may be high-concentration N-type impurity diffusion regions and may be simultaneously formed by an ion implantation process. Specifically, the source region 150 may be formed in a surface portion of the body region 106 adjacent to the gate electrode 142, and the drain region 152 may be formed in a surface portion of the drift region 108 adjacent to the field oxide layer 130.

Further, a body contact region 154 may be formed in a surface portion of the body region 106 adjacent to one side of the source region 150, and a gate spacer may be formed on side surfaces of the gate electrode 142. For example, the body contact region 154 may be a high-concentration P-type impurity diffusion region and may be formed by an ion implantation process.

In accordance with the embodiments of the present disclosure as described above, the surface portion 102A of the substrate 102 on which the field oxide layer 130 is formed may be convex upward, and thus, the moving distance of electrons moving from the source region 150 to the drain region 152 and the on-resistance of the semiconductor device 100 may be reduced. In addition, the interface between the field oxide layer 130 and the substrate 102 may be spaced upward from the movement path of the electrons. Accordingly, the HCI effect may be reduced, and the threshold voltage of the semiconductor device 100 may be stably maintained in comparison with the prior art using the field oxide pattern.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

1. A semiconductor device comprising:
a field oxide layer formed on a substrate;
a gate insulating layer formed on a surface portion of the substrate adjacent to one side of the field oxide layer;
a gate electrode formed on the gate insulating layer and a portion of the field oxide layer;
a source region formed in a surface portion of the substrate adjacent to one side of the gate electrode; and
a drain region formed in a surface portion of the substrate adjacent to another side of the field oxide layer,
wherein a surface portion of the substrate on which the field oxide layer is formed is convex upward.

2. The semiconductor device of claim 1, wherein the field oxide layer has a width that gradually increases downward.

3. The semiconductor device of claim 1, further comprising:
a drift region formed in the substrate; and
a body region formed in the substrate,
wherein the source region is formed in a surface portion of the body region, and the drain region is formed in a surface portion of the drift region.

4. The semiconductor device of claim 3, further comprising a body contact region formed in a surface portion of the body region adjacent to one side of the source region.

5. A method of manufacturing a semiconductor device, the method comprising:
forming a field oxide layer on a substrate;
forming a gate insulating layer on a surface portion of the substrate adjacent to one side of the field oxide layer;
forming a gate electrode on the gate insulating layer and a portion of the field oxide layer;
forming a source region in a surface portion of the substrate adjacent to one side of the gate electrode; and
forming a drain region in a surface portion of the substrate adjacent to another side of the field oxide layer,
wherein a surface portion of the substrate on which the field oxide layer is formed is convex upward while the field oxide layer is formed.

6. The method of claim 5, wherein forming the field oxide layer comprises:
forming a silicon layer on the substrate;
forming a hard mask pattern on the silicon layer to expose a portion of the silicon layer;
performing a first thermal oxidation process to oxidize the exposed portion of the silicon layer so that a preliminary field oxide layer having a bird's beak-shaped side portion is formed;
removing the hard mask pattern;
etching the silicon layer so that a ring-shaped silicon pattern remains under the side portion of the preliminary field oxide layer; and
performing a second thermal oxidation process to oxidize the ring-shaped silicon pattern so that the field oxide layer is formed.

7. The method of claim 6, wherein forming the field oxide layer further comprises forming a pad oxide layer on the substrate,
wherein the silicon layer is formed on the pad oxide layer.

8. The method of claim 7, wherein forming the field oxide layer further comprises removing the pad oxide layer after performing the second thermal oxidation process.

9. The method of claim 7, wherein the first thermal oxidation process is performed until the preliminary field oxide layer is reached on the pad oxide layer.

10. The method of claim 5, further comprising forming a body region and a drift region in the substrate before forming the field oxide layer,
wherein the source region is formed in a surface portion of the body region, and the drain region is formed in a surface portion of the drift region.

11. The method of claim 10, further comprising forming a body contact region in a surface portion of the body region adjacent to one side of the source region.

12. A method of manufacturing a semiconductor device, the method comprising:
forming a silicon layer on a substrate;
forming a hard mask pattern on the silicon layer to expose a portion of the silicon layer;
performing a first thermal oxidation process to oxidize the exposed portion of the silicon layer so that a preliminary field oxide layer having a bird's beak-shaped side portion is formed;
removing the hard mask pattern;
performing a first etch-back process so that a ring-shaped silicon pattern remains under the side portion of the preliminary field oxide layer;
performing a second thermal oxidation process to oxidize the ring-shaped silicon pattern so that a field oxide layer is formed;
performing a second etch-back process until the substrate is exposed;
forming a gate insulating layer on a surface portion of the substrate adjacent to one side of the field oxide layer;
forming a gate electrode on the gate insulating layer and a portion of the field oxide layer;
forming a source region in a surface portion of the substrate adjacent to one side of the gate electrode; and
forming a drain region in a surface portion of the substrate adjacent to another side of the field oxide layer.

13. The method of claim 12, further comprising forming a pad oxide layer on the substrate,
wherein the silicon layer is formed on the pad oxide layer.

14. The method of claim 13, wherein the pad oxide layer is removed by the second etch-back process.

15. The method of claim 13, wherein the first thermal oxidation process is performed until the preliminary field oxide layer is reached on the pad oxide layer.

16. The method of claim 12, further comprising forming a body region and a drift region in the substrate before forming the silicon layer,
wherein the source region is formed in a surface portion of the body region, and the drain region is formed in a surface portion of the drift region.

17. The method of claim 16, further comprising forming a body contact region in a surface portion of the body region adjacent to one side of the source region.
